(19) United States
(12) Patent Application Publication
(10) Pub. No.: US 2016/0033551 A1
(43) Pub. Date: Feb. 4, 2016

(54) SOCKET FOR TESTING SEMICONDUCTOR DEVICE

(71) Applicant: Meritech Co., Ltd., Hwaseong-si (KR)

(72) Inventors: Seung Nam KANG, Yongin-si (KR); Chae Young YUN, Hwaseong-si (KR)

(21) Appl. No.: 14/611,283

(22) Filed: Feb. 2, 2015

(30) Foreign Application Priority Data
Aug. 1, 2014 (KR) 10-2014-0099109

(51) Int. Cl. G01R 1/04; G01R 31/28

(52) U.S. Cl. CPC G01R 1/0466; G01R 31/2889

(57) ABSTRACT

A socket for testing a semiconductor to electrically connect electrodes of a test device and contact balls of a semiconductor device with each other, including: contactors each of which has an upper end portion protruding to one side from a vertical line and a lower end portion protruding to the other side in such a way as to have elasticity by a structure that the upper end portion and the lower end portion are symmetric with each other; insulation parts each of which is made of an insulating elastic material and is formed integrally with the contactor to absorb the force generated when coming in contact with the contactor; and guide films each of which is made with an insulating elastic body and is formed on an upper layer of the insulation part in order to align the contact balls of the semiconductor device and the contactors.

### BACKGROUND OF THE INVENTION

1. Field of the Invention

The present invention relates to a socket for testing a semiconductor device having S-shaped elastic contactors, and more particularly, to a socket for testing a semiconductor device having S-shaped elastic contactors which can reduce abrasion of a pad of a test device while testing the semiconductor device, adjust strokes to compensate a deviation of contact balls of the semiconductor device and is easy to manufacture.

2. Background Art

In general, various tests are carried out to electronic parts in order to confirm reliability of the products after manufacturing. There are a test on electrical characteristics to test normal operation and connected and disconnected states by connecting all input and output terminals of the electronic part to a test signal generation circuit and a burn-in test to check the lifespan and faults of the electronic parts by connecting some of input and output terminals, such as a power input terminal, of the electronic part with the test signal generation circuit and applying stress with temperature, voltage and current which are higher than normal operation conditions.

Such tests are carried out in a state where a conductive contactor electrically gets in contact with a contact ball of a semiconductor device after the electronic part is loaded on the conductive contactor. Moreover, the conductive contactor is generated determined in its shape according to the shape of the electronic part and serves as the medium to connect an electrode of the test device with a tested electrode of the electronic part through a mechanical contact.

Particularly, in a case of a ball grid array (BGA), which uses a solder ball as the tested electrode of the electronic parts, a socket is used to electrically connect a contact ball of the BGA-type semiconductor package with a pad of a printed circuit board (PCB) mounted on the test device for a test. Conventionally, a pogo type socket and a rubber type socket which is made of a rubber material have been used.

In a case of the pogo type socket, a force that the contactor receives from the semiconductor device must be applied at right angles to the pad of the test device, but it has a disadvantage in that the PCB pad of the test device is worn out because the force is applied not in the perpendicular direction but in different directions according to clearances of holes as the pogo pin is used more.

Moreover, with the trend of reduction in weight and thickness of electronic parts, people demand pogo pins of fine pitch, but it is difficult to test the semiconductor package on which electrodes of high density and fine pitch are arranged due to a technical limit in processing the pogo pin and price competitiveness.

The rubber type socket has disadvantages in that the outward appearance of the rubber socket is damaged and loses its restoring force due to a repeated contact with the contact balls and it is difficult to maintain uniform contact with the contact balls. Additionally, the rubber type socket also has disadvantages in that Au powder may be separated and it is difficult to form a generally uniform contact at the time of a test when there is deviation in height of the contact balls of the semiconductor package because an amount of strokes is less. Moreover, the rubber type socket has a limit in effectively providing an electric contact because it is difficult to transform ends of the contactors.

### SUMMARY OF THE INVENTION

Accordingly, the present invention has been made to solve the above-mentioned problems occurring in the prior arts, and it is an object of the present invention to provide a socket for testing a semiconductor device, which can make up actions to high density and fine pitch, abrasion of a pad of a test device and weakness to shock generated when it comes into contact with contact balls, which are disadvantages of the conventional pogo type socket, such that pins are arranged uniformly and accurately so as to provide an amount of strokes much more than the conventional rubber type socket, thereby providing reliability.

To accomplish the above object, according to the present invention, there is provided a socket for testing a semiconductor to electrically connect electrodes of a test device and contact balls of a semiconductor device with each other, the socket including: contactors each of which has an upper end portion protruding to one side from a vertical line and a lower end portion protruding to the other side in such a way as to have elasticity by a structure that the upper end portion and the lower end portion are symmetric with each other, and which transfer a force vertically generated to a Z-axis direction and elastically come in contact with the electrodes of the test device and the contact balls of the semiconductor device; insulation parts each of which is made of an insulating elastic material and is formed integrally with the contactor to absorb the force generated when coming in contact with the contactor; and guide films each of which is made with an insulating elastic body and is formed on an upper layer of the insulation part in order to align the contact balls of the semiconductor device and the contactors.

In another aspect of the present invention, there is provided a contactor for testing a semiconductor device which physically comes into contact in order to electrically connect electrodes of a test device and contact balls of a semiconductor device with each other, the contactor including: a crown tip having a plurality of sharp protrusions formed at positions which comes into contact with the contact balls of the semiconductor device; an upper end portion on which the crown tip is mounted and which protrudes to one side from a vertical line to have a curve structure or a polygonal structure; and a lower end portion which extends downwardly from the upper end portion and protrudes to the other side to have a curve structure or a polygonal structure, wherein the protruding portions of the upper end portion and the lower end portion are pressed in the inward direction when the contact balls of the semiconductor device come into contact with the electrodes of the test device, and then, is returned to their original positions when the contact state and the pressed state are released.

As described above, the socket for testing the semiconductor device having the S-shaped elastic contactor transfers the force generated in the vertical direction only to the Z-axis direction because the contactor has elasticity due to the structure of the upper end portion and the lower end portion that protrude symmetrically with each other from the vertical line, thereby reducing abrasion of the tester pad and allowing uniform contact with the contact balls of the semiconductor device due to the even pin force of contactor pins. Moreover, when the insulation part is formed, the amount of strokes can be controlled through adjustment of thickness and hardness of silicon so as to compensate height deviation of the contact balls of the semiconductor device. Furthermore, the contactor and the insulation part are formed integrally with elasticity, and hence, the force generated by contact is simultaneously applied to the contactor and the insulation part, such that the socket for testing the semiconductor device according to the preferred embodiment of the present invention is improved in the lifespan compared with the conventional rubber type socket.

### BRIEF DESCRIPTION OF THE DRAWINGS

The above and other objects, features and advantages of the present invention will be apparent from the following detailed description of the preferred embodiments of the invention in conjunction with the accompanying drawings, in which:

FIG. 1 is a sectional view showing the cross section of a socket for testing a semiconductor device having S-shaped elastic contactors according to a preferred embodiment of the present invention;

FIG. 2 is a perspective view of the socket for testing the semiconductor device having the S-shaped elastic contactors;

FIG. 3 is a view showing the S-shaped elastic contactors according to the preferred embodiment of the present invention;

FIG. 4 is a view showing a modification of the S-shaped elastic contactor; and

FIG. 5 is a view showing an upper structure of the contactor exposed between guide films.

### DETAILED DESCRIPTION OF THE PREFERRED EMBODIMENT

Reference will be now made in detail to the preferred embodiments of the present invention with reference to the attached drawings.

The example embodiments of the present invention are capable of various modifications and alternative forms, and particular embodiments of the present invention will be illustrated in the attached drawings and described in this specification in detail, but it should be understood that the scope of the present invention is not limited by the example embodiments which will be described in the following. The preferred embodiments are provided to describe the present invention to persons who have average knowledge in the art more perfectly. Therefore, in the attached drawings, shapes and dimensions of the components are more enlarged than they actually are in order to clarify the present invention. In the drawings, the same components have the same reference numerals even though they are illustrated in different figures. In addition, in the description of the present invention, when it is judged that detailed descriptions of known functions or structures related with the present invention may make the essential points vague, the detailed descriptions of the known functions or structures will be omitted.

With reference to the attached drawings, example embodiments of a socket for testing a semiconductor device having S-shaped elastic contactors according to the present invention will be described in detail.

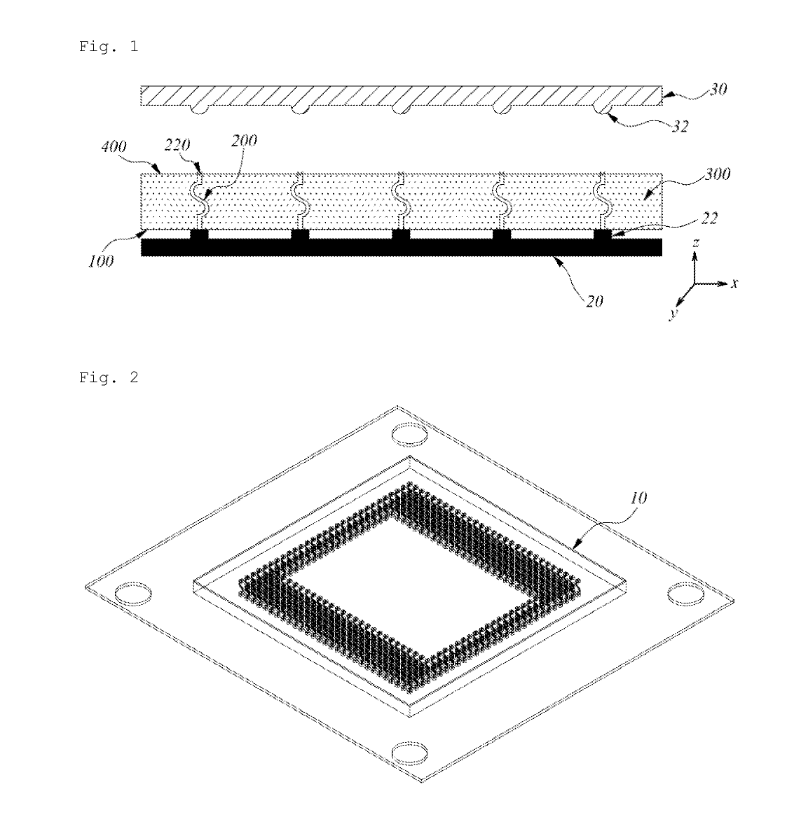

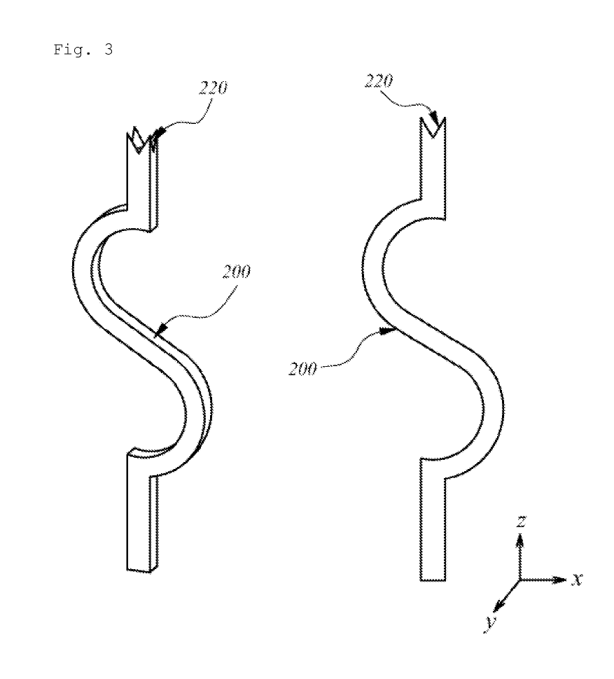

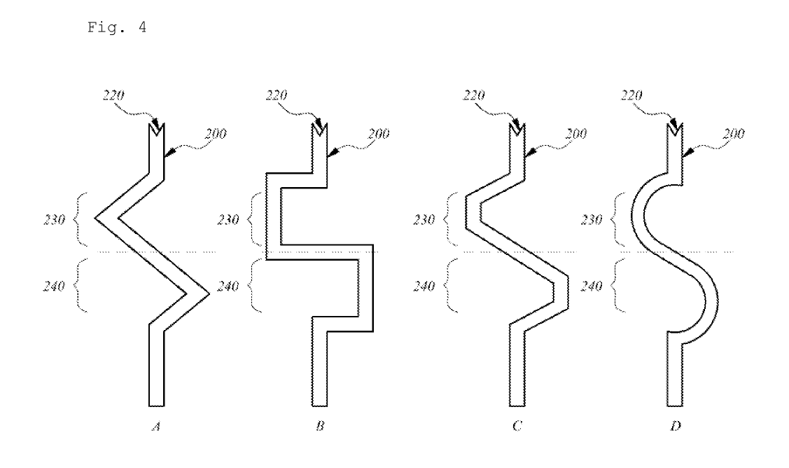

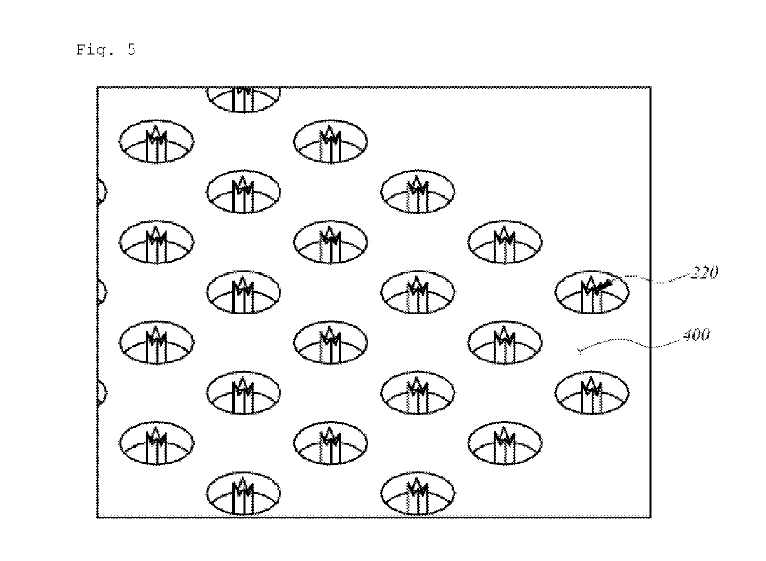

FIG. 1 is a sectional view showing the cross section of a socket for testing a semiconductor device having S-shaped elastic contactors according to a preferred embodiment of the present invention, FIG. 2 is a perspective view of the socket for testing the semiconductor device having the S-shaped elastic contactors, FIG. 3 is a view showing the contactor of the socket for testing the semiconductor device having the S-shaped elastic contactors according to the preferred embodiment of the present invention, FIG. 4 is a view showing a modification of the S-shaped elastic contactors, and FIG. 5 is a view showing an upper structure of the contactor exposed between guide films.

Referring to FIG. 1, the socket 10 for testing the semiconductor device having the S-shaped elastic contactors according to the preferred embodiment of the present invention is located between a test device 20 and a semiconductor device 30, and includes a fixing frame 100, a plurality of contactors 200, insulation parts 300 and guide films 400.

The fixing frame 100 is disposed to align the contactors 200 and electrodes 22 of the test device, and has a plurality of through holes which are vertically formed through the fixing frame 100 at positions corresponding to the contactors 200.

The contactors 200 are vertically aligned at positions corresponding to the through holes formed in the fixing frame 100. The upper end of the contactor 200 gets in contact with a contact ball 32 of the semiconductor device and the lower end gets in contact with the electrode 22 of the test device, such that the contact ball 32 of the semiconductor device is electrically connected with the electrode 22 of the test device.

Particularly, as shown in FIGS. 3 and 4, an upper end portion 230 and a lower end portion 240 of the contactor 200 protrude from a vertical line in such a way as to be symmetric with each other and have elasticity, such that the contactor 200 transfers a vertically generated force only in the vertical direction, namely, in the Z-axis direction. Due to such a structure of the contactor 200, the contactor 200 can get in elastic contact with the electrode 22 of the test device and the contact ball 32 of the semiconductor device. When the contactor 200 comes into contact with the electrode 22 of the test device and the contact ball 32 of the semiconductor device, because the contact transfers the applied force only in the Z-axis direction even though it is pressed, it can reduce abrasion of the electrode pad of the test device by preventing the force from being applied in the X and Y directions.

Furthermore, due to the structure of the contactor 200, the contactors 200 have uniform pin forces, such that the contactors 200 can uniformly get in contact with the contact balls 32 of the semiconductor device.

As shown in FIG. 3, the upper end portion 230 and the lower end portion 240 of the contactor 200 have a curve structure that the upper end portion 230 protrudes to one side from the vertical line and the lower end portion 240 protrudes to the other side to be symmetrical with the upper end portion 230. As described above, the contactor 200 has elasticity due to the curve structure with bidirectional symmetry.

Such a contactor 200 which has the upper end portion 230 and the lower end portion 240 in the curve structure with bidirectional symmetry may be called an S-shaped elastic contactor.

In the meantime, the S-shaped elastic contactor may be somewhat transformed in the curve structure with bidirectional symmetry. For instance, as shown in FIG. 4, the upper end portion 230 of the contactor 200 may protrude to one side from the vertical line in a polygonal form and the lower end portion 240 may protrude to the other side in a polygonal form to be symmetric with the upper end portion 230. In FIG. 4, (A) illustrates a structure that the upper end portion 230 and the lower end portion 240 protrude in a triangular form, (B) illustrates a structure that the upper end portion 230 and the lower end portion 240 protrude in a rectangular form, (C) illustrates a structure that the upper end portion 230 and the lower end portion 240 protrude in a semi-hexagonal form, and (D) illustrates a structure that the upper end portion 230 and the lower end portion 240 protrude in a semi-octagonal form.

The contactor 200 is made of an alloy of at least one among nickel, iron, cobalt, beryllium, gold, silver, palladium and rhodium and is manufactured through the MEMS fabrication.

Moreover, various crown tips 220 are respectively mounted on the tops of the contactors 200. The crown tip 220 has a crown shape and is formed at the top of the contact in order to increase a contact force with the contact ball 32 of the semiconductor device. As shown in FIG. 5, the crown tip 220 is exposed by the through hole formed in the guide film 400 and goes in and out through the through hole by an elastic motion of the contactor 200. Now, a manufacturing method of the socket will be described. First, the contactor 200 is manufactured through the MEMS fabrication including photolithography and electroplating processes, and then, the crown tip manufactured through the MEMS fabrication is combined to the contactor 200. Because the contactor 200 and the crown tip 220 are manufactured through the MEMS fabrication, it is easy to manufacture the socket with high density and fine pitch.

The insulation part 300 is made of an insulating elastic material, and is formed integrally with the contactor 200. In detail, first, the insulation part 300 is formed integrally with the contactor 200 after liquid-phase silicon is hardened onto the aligned contactor 200. The insulation part 300 formed of the liquid phase silicon which is hardened integrally with the contactor 200 provides a double elastic function together with the contactor 200 which has elasticity. Therefore, a force generated by physical contact is simultaneously absorbed to the contactor 200 and the insulation part 300 so as to improve durability of the socket more than the conventional rubber type socket.

Particularly, when hardness or thickness of the liquid phase silicon of the insulation part 300 is controlled, an amount of test strokes can be secured and a pin force of the contactor 200 can be controlled. Therefore, the amount of strokes to compensate height deviation of the contact balls of the semiconductor device can be prepared.

The guide film 400 is made with an insulating elastic body in order to insulate the contactors 200 from each other. Additionally, the guide film 400 is formed on the insulation part 300 for alignment of the contact balls 32 of the semiconductor device and the contactors 200, and includes a plurality of the holes to expose the upper ends of the contactors 200. Because the guide film 400 has elasticity, it can absorb shock applied to the contactor 200 at the time of contact, so as to prevent abrasion and damage of the socket 10 for testing the semiconductor device. The guide film 400 may be made of, for instance, a material of polyimide group.

The semiconductor device 20 is tested using the socket for testing the semiconductor device having the S-shaped elastic contactor according to the preferred embodiment of the present invention as follows.

First, the socket 10 for testing is loaded on the test device 20 on which the electrodes 22 of the test device are arranged. That is, the contactors 200 are arranged in such a manner that the lower ends of the contactors 200 respectively come in contact with the electrodes 22 of the test device. After that, the contact balls 32 of the semiconductor device get in contact with the tops of the contactors 200, namely, crown tips 220, while the semiconductor device 30 lowers. In this instance, when the semiconductor device 30 lowers more, the semiconductor device 30 presses the contactors 200, and then, the contact balls 32 of the semiconductor device and the electrodes 22 of the test device respectively get in contact with the tops and bottoms of the contactors 200 by conductivity of the contactors 200 so as to be in an electrically connectable state. Here, because the upper end portion 230 and the lower end portion 240 have elasticity, while the contactors 200 are pressed, the protruding structure is pressed in the inward direction. When the contact state is released, the pressed state is also released, and then, the pressed protruding structure is returned to its original state. When an electric signal is applied from the test device 20, the signal is transferred to the contact balls 32 of the semiconductor device through the socket 10, such that a test is carried out.

Here, when the semiconductor device lowers, the force applied to the contactors 200 is absorbed by the double elastic function of the contactors 200 having elasticity and the insulation part 300 which is formed integrally with the contactors 200 using the elastic material, thereby reducing abrasion of the socket and increasing the lifespan.

Meanwhile, the socket can test not only the semiconductor device of which the contact balls 32 vertically come into one-to-one contact with the contactors 200 but also the semiconductor device which has different contact positions in the vertical direction. Because the insulation parts are formed integrally with the contactors 200, the socket can minimize contact noise even in a repeated contact condition and in a high frequency test condition, thereby maintaining the characteristics of the products.

The socket for testing according to the preferred embodiment of the present invention is lower in loop inductance than the conventional rubber type socket so as to reduce current path, such that the socket can be used not only to the conventional semiconductor devices but also high speed devices.

As described above, the socket for testing the semiconductor device having the S-shaped elastic contactor transfers the force generated in the vertical direction to the Z-axis direction because the contactor has elasticity, thereby reducing abrasion of the tester pad and allowing uniform contact with the contact balls of the semiconductor device due to the even pin force of contactor pins.

Moreover, when the insulation part is formed, the amount of strokes can be controlled through adjustment of thickness and hardness of silicon so as to compensate height deviation of the contact balls of the semiconductor device.

Furthermore, the contactor and the insulation part are formed integrally with elasticity, and hence, the force generated by contact is simultaneously applied to the contactor and the insulation part, such that the socket according to the preferred embodiment of the present invention is improved in the lifespan compared with the conventional rubber type socket.

Additionally, because the contactors and the crown tips are manufactured through the MEMS fabrication, the socket of high density and fine pitch can be easily manufactured.

As described above, while the present invention has been particularly shown and described with reference to the example embodiments thereof, it will be understood by those of ordinary skill in the art that the above embodiments of the present invention are all exemplified and various changes, modifications and equivalents may be made therein without changing the essential characteristics and scope of the present invention. Therefore, it would be understood that the present invention is not limited to the forms described in the example embodiments and the technical and protective scope of the present invention shall be defined by the following claims. In addition, it should be also understood that all modifications, changes and equivalences within the technical scope of the present invention defined by the following claims belong to the technical scope of the present invention.

1. A socket for testing a semiconductor device to electrically connect electrodes of a test device and contact balls of a semiconductor device with each other comprising:
contactors each of which has an upper end portion protruding to one side from a vertical line and a lower end portion protruding to the other side so as to have elasticity by a structure that the upper end portion and the lower end portion are symmetric with each other, thereby transferring a force vertically generated to a Z-axis direction and coming into elastic contact with the electrodes of the test device and the contact balls of the semiconductor device;
insulation parts each of which is made of an insulating elastic material and is formed integrally with the contactor to absorb the force generated when coming in contact with the contactor; and
guide films each of which is made with an insulating elastic body and is formed on the insulation part in order to align the contact balls of the semiconductor device and the contactors.

2. The socket according to claim 1, wherein the upper end portion protruding to one side from the vertical line and the lower end portion protruding to the other side to be symmetric with the upper end portion are formed to have a curved structure or a polygonal structure.

3. The socket according to claim 1, wherein the contactor has a crown tip having a plurality of sharp concave-convex forms at the upper end portion which comes into contact with the contact ball of the semiconductor device.

4. The socket according to claim 1, further comprising:
a fixing frame which is disposed to align the contactors and electrodes of the test device and has a plurality of through holes which are vertically formed through the fixing frame at positions corresponding to the contactors.

5. The socket according to claim 1, wherein the insulation part is formed integrally with the contactor when liquid-phase silicon is hardened onto the aligned contactor.

6. The socket according to claim 5, wherein the insulation part controls an amount of strokes by adjusting thickness and hardness of the liquid-phase silicon thereof so as to compensate height deviation of the contact balls of the semiconductor device.

7. The socket according to claim 5, wherein the socket controls a contact force of the contactor by adjusting hardness of the liquid-phase silicon.

8. The socket according to claim 1, wherein the socket provides a double elasticity function through elasticity of the contactors and elasticity of the insulation parts which are formed of the liquid-phase silicon to be hardened integrally with the contactors.

9. The socket according to claim 1, wherein the contactors and the crown tips are manufactured through the MEMS fabrication and are made of an alloy of at least one among nickel, iron, cobalt, beryllium, gold, silver, palladium and rhodium.

10. A contactor for testing a semiconductor device which physically comes into contact in order to electrically connect electrodes of a test device and contact balls of a semiconductor device with each other, the contactor comprising:
a crown tip having a plurality of sharp protrusions formed at positions which comes into contact with the contact balls of the semiconductor device;
an upper end portion on which the crown tip is mounted and which protrudes to one side from a vertical line to have a curved structure or a polygonal structure; and
a lower end portion which is connected to the lower side of the upper end portion and protrudes to the other side to have a curved structure or a polygonal structure,
wherein the protruding portions of the upper end portion and the lower end portion are pressed in the inward direction when the contact balls of the semiconductor device come into contact with the electrodes of the test device, and then, is returned to their original positions when the contact state and the pressed state are released.

11. The socket according to claim 3, wherein the contactors and the crown tips are manufactured through the MEMS fabrication and are made of an alloy of at least one among nickel, iron, cobalt, beryllium, gold, silver, palladium and rhodium.
